(19) United States
(12) Patent Application Publication
(10) Pub. No.: US 2008/0128024 A1
(43) Pub. Date: Jun. 5, 2008

(54) Open air manufacturing process for producing biologically optimized photovoltaic cells

(76) Inventors: Reginald Parker, Tallahassee, FL (US); Ray O'Neal, Tallahassee, FL (US); Jesse Edwards, Tallahassee, FL (US)

Correspondence Address: Jerome J. Norris/Norris, Braden;Melton & Gregersen, PLLC, Suite 305, 1901 Pennsylvania Avenue, N.W., Washington, DC, 20006, US

(21) Appl. No.: 11/607,017

(22) Filed: Dec. 1, 2006

(51) Int. Cl. H01L 31/04

(52) U.S. Cl. 136/263; 977/750

(57) ABSTRACT

A method for production of electricity from light, comprising:
contacting with light a heterojunction device with a clear film anode of ITO and a cathode of Al, said device having:
i) a donor/acceptor blend in a single layer, wherein the donor domains is a synthetic polymer, and the acceptor domains is a) a dry organic semiconductor composite of sonicated single walled carbon nanotubes (SWNTs) wetted with epon 862 epoxy resin, and b) a biopolymer selected from lignin or melanin.

### FIELD OF THE INVENTION

The present invention relates to improved efficiency photovoltaic cells having a donor/acceptor blend in a single or monolayer prepared in an open air manufacturing process using dry and/or liquid organic semiconductor composites of dispersions of carbon nanotubes, dispersants, synthetic polymers, and biological polymers of lignin and melanin to produce low costs, high efficiency solar cells.

### BACKGROUND OF THE INVENTION

### Description of the Related Art

Photovoltaic cells generally employ thin layers of semiconductor material, such as crystalline silicon and gallium arsenide and incorporate a p-n junction to convert solar energy to direct current. Although these devices are useful in many applications, their efficiency is limited, as the conversion efficiencies of solar power to electrical power are just better than only 10%. And even though efficiencies of these devices are improving, the improvements are due to costly improvements to the device structure, and the prevailing consensus is that the physical limitations on these devices are such that the maximum efficiency to be expected would be about 30%. For ordinary public consumption, these energy requirements are relatively inefficient, and this combined with their high cost compared to other means of energy generation have resulted in limited wide spread use of solar energy for consumer markets.

Unfortunately, the limited usages have essentially been where conventionally generated electricity is not readily available, such as in remote areas or where the cost of bringing conventionally generated electricity to a specific locale would more closely approximate the costs of the photovoltaic system.

Also, due to the construction and efficiency of presently marketed photovoltaics, there is a corresponding exactness of the physical requirements of these photovoltaics. That is, due to the relative inefficiency along with the rigid construction requirements, photovoltaic systems generally require a flat space and adequate sun exposure at all times—or during peak times, to meet electricity requirements where the system is used.

U.S. Patent Application Serial No. 2004/231719 disclose a regenerative photovoltaic cell (1) producing a visible light-induced photocurrent comprising a transparent or translucent first substrate (2) having a back surface coated with an indium tin oxide (ITO) layer (4), a nano-structured photoanode (5) comprising an n-type semiconductor (6) i.e.,titanium dioxide, coated with a broad band absorbing melanin-like material (7), a second substrate (8) with a carbon/platinum coating (9) forming a counter cathode and a liquid electrolyte (14) between the photoanode and cathode, wherein the electrolyte re-oxidizes the melanin-like material (7) after it has absorbed incident radiation, to return it to the ground state. A p-i-n type photovoltaic cell is also exemplified in addition to other electronic devices employing melanin-like materials and processes for the production of mechanically stable, flexible films of melanin-like material for use in electronic devices.

A photovoltaic transducer is disclosed in U.S. Patent Application No. 2006/0035392. The photoelectric transducer includes a semiconductor film as a thin film electrode, that is photosensitized by one or multiple lignin derivatives consisting of: (a) a lignophenol derivative or a phenol derivative of lignin prepared by solvating a lignin-containing material with a phenol compound and adding an acid to the solvate; (b) a secondary derivative prepared by one reaction of the lignophenol derivative (a) selected among acylation, carboxylation, amidation, introduction of a crosslinking group, and alkali treatment; (c) a higher-order derivative prepared by at least two reactions of the lignophenol derivative (a) selected among acylation, carboxylation, amidation, introduction of the crosslinking group, and alkali treatment; (d) a crosslinked secondary derivative prepared by crosslinking the secondary derivative (b) obtained by the introduction of the crosslinking group; and (e) a crosslinked higher-order derivative that is prepared by crosslinking the higher-order derivative (c) obtained by the introduction of the crosslinking group.

U.S. Pat. No. 7,087,833 disclose nanocomposite photovoltaic devices that include semiconductor nanocrystals as at least a portion of a photoactive layer. Photovoltaic devices and other layered devices that comprise core-shell nanostructures and/or two populations of nanostructures, where the nanostructures are not necessarily part of a nanocomposite, are also featured. Varied architectures for such devices are also provided including flexible and rigid architectures, planar and non-planar architectures, as are systems incorporating such devices, and methods and systems for fabricating such devices.

An effective way of constructing high performance biological light electrodes is disclosed in Chinese Patent No. 1558222. By means of modifying various mutants of extracted purple bacteria photosynthesis reaction center protein (RC) to specific nano semiconductor substrate, composite light electrode with high efficiency photoelectronic conversion function in wide wavelength range, especially in near infrared area may be obtained. On one side, these artificially modified RC has even higher photoelectronic conversion efficiency than natural RC. On the other side, adopting nano semiconductor material, especially mesoporous semiconductor material, can promote the photoelectronic conversion of RC while realizing the efficient fixation of RC. The modified and optimized RC has a sensitizing effect on nano semiconductor, and this raises greatly the absorption and utilization of composite light electrode on solar energy and is favorable to developing efficient solar energy cell.

U.S. Pat. No. 5,454,880 disclose fabrication of heterojunction diodes from semiconducting (conjugated) polymers and acceptors such as fullerenes, particularly Buckminsterfullerenes, C60, and more particularly to the use of such heterojunction structures as photodiodes and as photovoltaic cells.

There is still the need as well as interest in expanding usage of solar electricity. More specifically, there is a need for improved photovoltaic cells with increased energy conversion efficiency and cheaper manufacturing costs, together with improved flexibility of use and improved durability and longevity of the cell.

### SUMMARY OF THE INVENTION

One object of the invention is to provide an open air manufacturing process for producing the highest achievable photoelectric effect in photovoltaic cells by increasing photon absorption and exciton generation using spectrally tuned naturally occurring and synthetic polymers in a monolayer having a distribution of donor and acceptor domains.

Another object of the invention is to provide the highest achievable photoelectric effect in photovoltaic cells by increasing exciton separation by creating efficient e-fields using materials with highly differentiated chemical potentials through innovative dispersion processes that blend the donor/acceptor into a single layer comprising donor domains and acceptor domains.

A further object of the invention is to provide the highest achievable photoelectric effect in photovoltaic cells by increasing the charge carrier transport via magnetically aligned metallic buckypaper.

These and other objects of the invention will become more apparent by reference to the Brief Description Of the Drawings and Detailed Description of the Preferred Embodiments of the Invention.

### BRIEF DESCRIPTION OF THE DRAWINGS

FIG. 1 is a schematic of the biologically optimized photovoltaic cell of the invention.

FIG. 2 is a schematic of the process for preparing dried buckywood composite layer.

FIG. 3 is a graph showing milliamps versus millivolts or the forward bias I-V curve for the high fill factors (45-60%) of the biologically optimized photovoltaic cells of the invention.

FIG. 4 is a schematic showing organic compositions in various photovoltaic cells.

FIG. 5 is a graph showing short circuit current versus open circuit voltage for various photovoltaic cells, and the photovoltaic cells of the invention are depicted in the ellipse.

FIG. 6 is a graph showing power for various photovoltaic cells, and the photovoltaic cells of the invention are depicted in the ellipse.

### DETAIL DESCRIPTION OF PREFERRED EMBODIMENT OF THE INVENTION

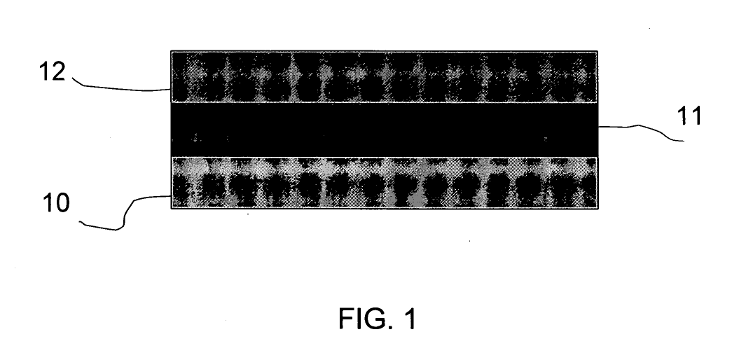

Reference is now made to FIG. 1, which is a schematic of the biologically optimized photovoltaic cell of the invention. In this cell, there can be seen a layer of a metal cathode 10, which is preferably aluminum. The buckywood composite layer 11 is disposed between the metal cathode layer and clear film anode 12, which is preferably indium tin oxide (ITO).

The entire range of the electromagnetic spectrum or radiant energies or wave frequencies from the longest to the shortest wavelengths are as follows:

Gamma, x-rays, UV, visible, IR, microwave, and RF.

Solar cells are generally spectrum specific in that they are generally designed to work within the UV, visible and IR range so as to match the absorption spectrum of the active element of the device to the solar spectrum range. The composite layer 11 disposed between the anode and metal cathode of the cell of the invention may be the buckywood composite and/or opti-glu.

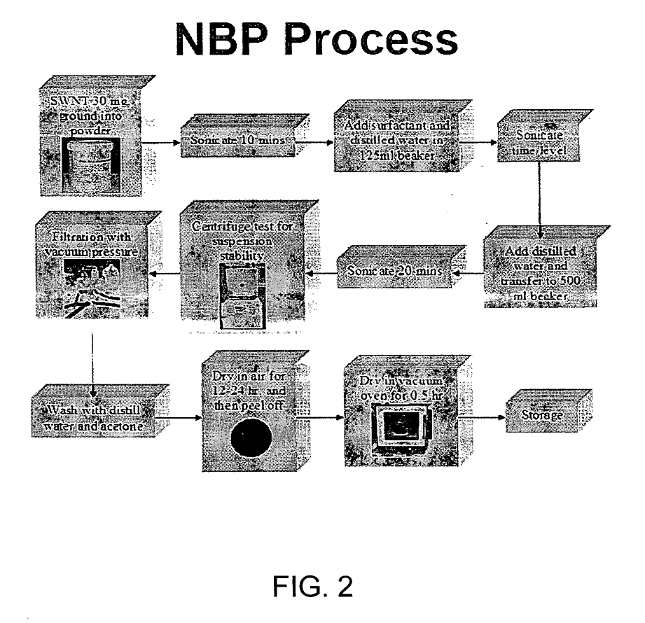

Buckywood composites were formed from blending single-walled carbon nanotubes (SWNTs) as shown by the process of FIG. 2 with the biological polymers (lignin and/or melanin) and using a multi-step dispersion and filtration processes of the suspension.

In the process of FIG. 2 sonication applies sound (ultrasound) energy through “a sonicator”—a bath of water through which sound is transmitted to help agitate particles within a vessel being sonicated. This speeds dissolution of the particles and is especially helpful when physically stirring is not possible. It also provides the energy for chemical reactions to proceed. The three sonication steps of the process help create the e-fields between materials with highly differentiated chemical potentials that are made close enough through dispersion.

The components of opti-glu suspension contain about 14% carbon nanotubes, about 57% of a biopolymer of either lignin or melanin, and about 29% of iodine by weight as a dopant. Other components or property modifiers may be thickeners, or charged semiconductor particles—so long as these other components do not dilute the opti-glu to less than 90% by weight.

Buckywood composites is a filtrand as a result of filtration of an optiglu suspension.

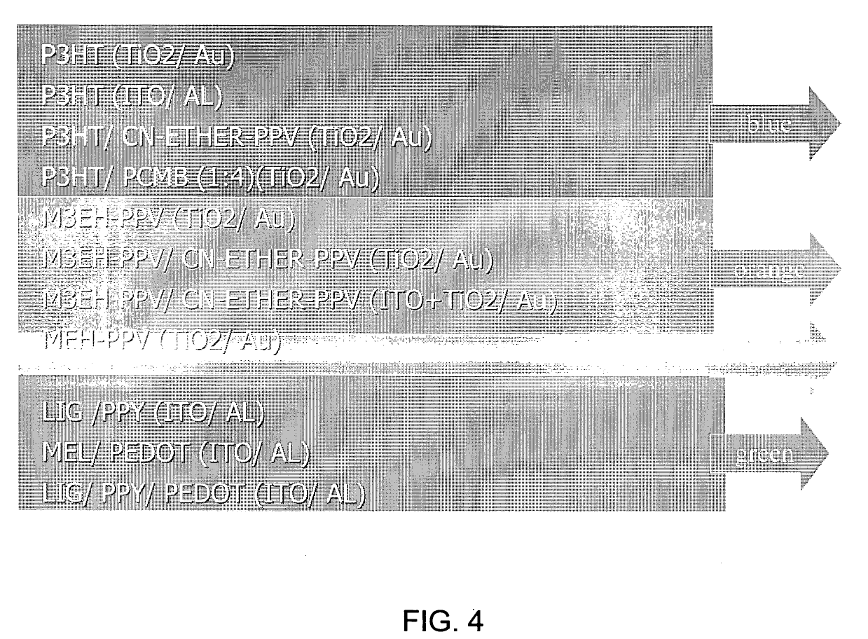

The clear ITO anode layer may be coated with glass or a flexible plastic, and the glass or flexible plastic may be coated with organic materials such as poly-(3-hexylthiophene)=P3HT or any of the polymers shown in the schematic of FIG. 4 to facilitate hole conduction and smooth the rough ITO layer to prevent shorts in the solar cell.

The compositions of these synthetic polymers on specific cell structures are:
poly-(3-hexylthiophene)=P3HT (TiO2/Au)
poly-(3-hexylthiophene)=P3HT (ITO/AL)
poly-(3-hexylthiophene)=P3HT/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (TiO2/Au)
poly-(3-hexylthiophene)=P3HT/methanofullerene 6,6-phenyl C₆₁-butyric acid methyl ester=PCMB (1:4)(TiO2/Au)
(poly[2,5-dimethoxy-1,4-phenylene-1,2-ethenylene-2-methoxy-5-(2-ethylhexyloxy)-(1,4-phenylene-1,2-ethenylene)])=M3EH-PPV (TiO2/Au)
(poly[2,5-dimethoxy-1,4-phenylene-1,2-ethenylene-2-methoxy-5-(2-ethylhexyloxy)-(1,4-phenylene-1,2-ethenylene)])=M3EH-PPV/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (TiO2/Au)
(poly[2,5-dimethoxy-1,4-phenylene-1,2-ethenylene-2-methoxy-5-(2-ethylhexyloxy)-(1,4-phenylene-1,2-ethenylene)]) M3EH-PPV/(poly[oxa-1,4-phenylene-1,2-(1-cyano)ethenylene-2,5-dioctyloxy-1,4-phenylene-1,2-(2-cyano)ethenylene-1,4-phenylene])=CN-ETHER-PPV (ITO+TiO2/Au)
poly(2-methoxy-5-(2′-ethyl-hexyloxy)-1,4-phenylene vinylene=MEH-PPV (TiO2/Au)
LIG/polypyrrole=PPY (ITO/AL)
MEL/Poly(3,4,-ethylenedioxythiopene)=PEDOT (ITO/AL)
LIG/polypyrrole=PPY/Poly(3,4,-ethylenedioxythiopene)=PEDOT (ITO)/AL)

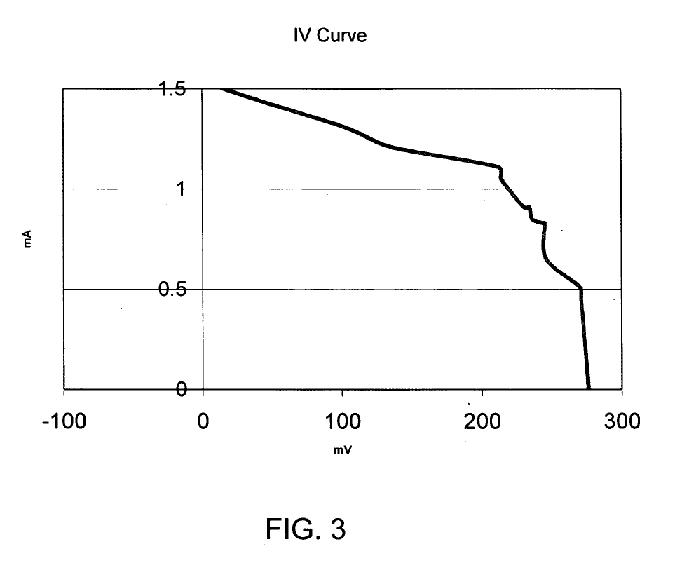

FIG. 3 is a graph of the forward bias I-V curve that provides high fill factors for a 7′×7′ solar cell, as depicted in mA versus mV. The fill factor here is 55% and the cell efficiency is about 4.11%.

While not wishing to be bound by any theory in reference to the dynamics of the biologically optimized photovoltaic ITO/Al architecture of the invention, it is nevertheless believed that incident UV, visible and IR portions of the electromagnetic spectrum that give rise to green photons are absorbed by the biopolymer of lignin or melanin in use with the ITO/AL cell to produce a photocurrent. The ITO/AL architecture of the cell of the invention is less expensive than the sol-gel gold (TiO₂/Au) architecture—and in this connection, it should be noted from FIG. 4 that the architecture of the composition of organic photovoltaic devices using TiO₂/Au cells capture blue, orange and gray photons as opposed to the green photons shown by the invention cells employing lignin and melanin with ITO/Al.

The propensity for photovoltaic cells to become contaminated has usually necessitated that the manufacturing process by carried out in an environment of either clean air or under a nitrogren blanket, and this requires specialized equipment which increases the manufacturing costs. However, the photovoltaic cells of the present invention can be manufactured in the open air, and therefore eliminates the need for specialized equipment to prevent contamination.

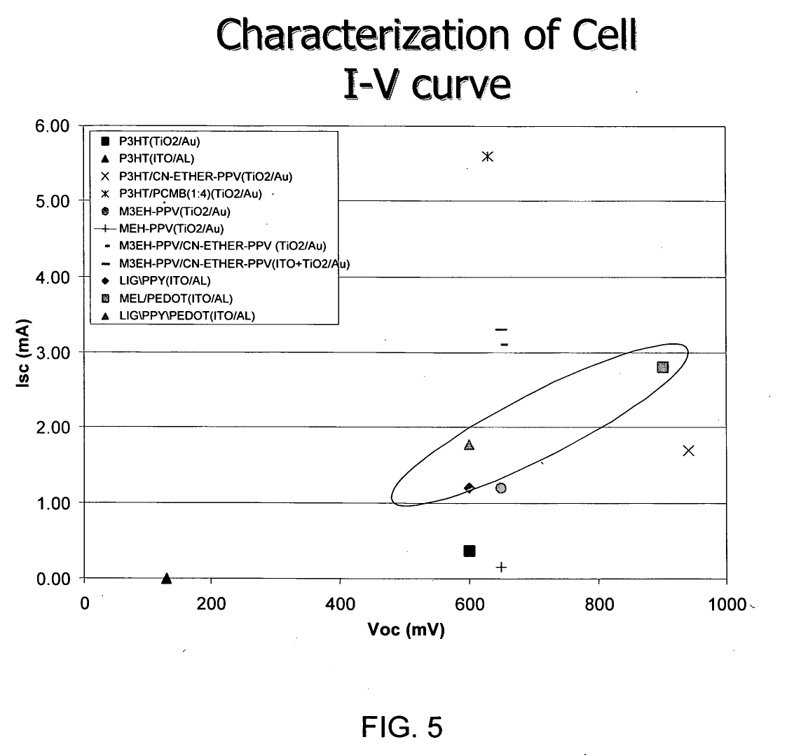

A characterization of cell I-V curves showing current density is shown in FIG. 5, wherein a graph shows short circuit current versus open circuit voltage for various types of biopolymers having a photoactive element used to sensitize the photoanode formed from an electrically conductive substrate. In FIG. 5, the ITO/Al photovoltaic cells of the invention using lignin or melanin is designated by the diamond, square or triangle shown in the elipse.

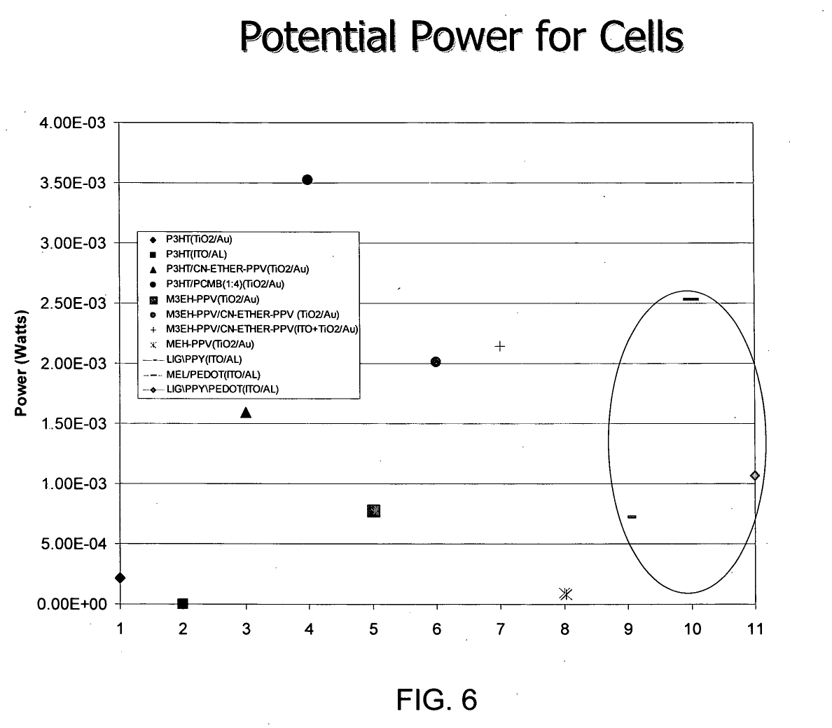

The power potential for the photovoltaic cells of the invention with the ITO/Al architecture in which the n-type semiconductor is coated with a broad band absorbing biopolymer such as lignin or melanin is represented by the symbols that are shown inside of the ellipse in FIG. 6.

It should be understood from the foregoing that variations of the invention are encompassed, and these variations and changes in form and detail can be made by those skilled in the art without departing from the scope of the invention, which is set forth in the appended claims, as follows:

We claim:

1. A method for production of electricity from light, comprising:
contacting with light a heterojunction device with a clear film anode of ITO and a cathode of Al, said device having:
i) a donor/acceptor blend in a single layer, wherein the donor domains is a synthetic polymer, and the acceptor domains is a) a dry organic semiconductor composite of sonicated single walled carbon nanotubes (SWNTs) wetted with epon 862 epoxy resin, and b) a biopolymer selected from lignin or melanin.

2. A method for production of electricity from light, comprising:
contacting with light a heterojunction device with a clear film anode of ITO and a cathode of Al, said device having:
i) a donor/acceptor blend of a single layer, wherein the donor domains is a synthetic polymer, and the acceptor domains is
a) a liquid organic semiconductor composite comprising, by weight about 14% single walled carbon nanotubes (SWNTs), about 57% of a biopolymer selected from lignin or melanin, and a dopant selected from the group consisting of iodine, phosphorous or boron.

3. The method of claim 1 wherein said dry organic semiconductor composite is mixed with a liquid semiconductor composite comprising, by weight, about 14% carbon nanotubes, about 57% of a biopolymer selected from lignin or melanin, and about 29% of a dopant selected from the group consisting of iodine, phosphorous and boron.

4. A photovoltaic cell for production of electricity from light, comprising a heterojunction with a clear film anode of ITO and a cathode of Al, said photovoltaic cell having:
i) a donor/acceptor blend in a single layer, wherein the donor domains is a synthetic polymer, and the acceptor domains is a) a dry organic semiconductor composite of sonicated single walled carbon nanotubes (SWNTs) wetted with epon 862 epoxy resin, and b) a biopolymer selected from lignin or melanin.

5. A photovoltaic cell for production of electricity from light, comprising a heterojunction with a clear film anode of ITO and a cathode of Al, said photovoltaic cell having:
i) a donor/acceptor blend of a single layer, wherein the donor domains is a synthetic polymer, and the acceptor domains is
a) a liquid organic semiconductor composite comprising, by weight about 14% single walled carbon nanotubes (SWNTs), about 57% of a biopolymer selected from lignin or melanin, and a dopant selected from the group consisting of iodine, phosphorous and boron.

6. The photovoltaic cell of claim 4 wherein said dry organic semiconductor composite is mixed with a liquid semiconductor composite comprising, by weight, about 14% carbon nanotubes, about 57% of a biopolymer selected from lignin or melanin, and about 29% of iodine as a dopant.

7. The photovoltaic cell of claim 4 wherein said synthetic polymer is PPY.

8. The photovoltaic cell of claim 4 wherein said synthetic polymer is PEDOT.

9. The photovoltaic cell of claim 4 wherein said synthetic polymer is PPY/PEDOT.

10. The photovoltaic cell of claim 5 wherein said synthetic polymer is PPY.

11. The photovoltaic cell of claim 5 wherein said synthetic polymer is PEDOT.

12. The photovoltaic cell of claim 5 wherein said synthetic polymer is PPY/PEDOT.

13. The photovoltaic cell of claim 6 wherein said synthetic polymer is PPY.

14. The photovoltaic cell of claim 6 wherein said synthetic polymer is PEDOT.

15. The photovoltaic cell of claim 6 wherein said conjugated polymer is PPY/PEDOT.

16. An open air process for manufacturing a photovoltaic cell comprising:
providing a clear film anode of ITO;
providing a cathode of Al; and
disposing between said anode and said cathode layers a donor/acceptor blend in a single layer, wherein the donor domains is a synthetic polymer, and the acceptor domains is a) a dry organic semiconductor composite of sonicated single walled carbon nanotubes (SWNTs) wetted with epon 862 epoxy resin, and b) a biopolymer selected from lignin or melanin to form a heterojunction device.

17. An open air process for manufacturing a photovoltaic cell comprising:
providing a clear film anode of ITO;
providing a cathode of Al, and disposing between said anode and said cathode layers.
ii) a donor/acceptor blend of a single layer, wherein the donor domains is a synthetic polymer, and the acceptor domains is
a) a liquid organic semiconductor composite comprising, by weight about 14% single walled carbon nanotubes (SWNTs), about 57% of a biopolymer selected from lignin or melanin, and a dopant selected from the group consisting of iodine, phosphorous or boron to form a heterojunction.
